(19) United States
(12) Patent Application Publication
(10) Pub. No.: US 2025/0343185 A1
(43) Pub. Date: Nov. 6, 2025

(54) HYBRID BONDING IN TOPOGRAPHIC PACKAGES

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 18/655,033

(22) Filed: May 3, 2024

(51) Int. Cl. H01L 23/00; H01L 23/31; H01L 23/48; H01L 23/538; H01L 25/00; H01L 25/065

(52) U.S. Cl. CPC H01L 24/08; H01L 23/481; H01L 24/09; H01L 25/0652; H01L 23/3107; H01L 23/538; H01L 24/24; H01L 25/50; H01L 2224/08145; H01L 2224/08225; H01L 2224/09181; H01L 2224/24137; H01L 2225/06562

(57) ABSTRACT

Electronic components and methods. The electronic components include a first device die and a first dummy die located in the first device level and having at least one first pass through conductive layer through the first dummy die. Also included is a second device die and a second dummy die located in a second device level above the first device level, the second device die attached to the first device die and the second dummy die attached to the first dummy die and having at least one second pass through conductive layer electrically connected to the at least one first pass through conductive layer. Also included is a third device die located in a third device level above the second device die, the third device die attached to at least one of a top surface of the second device die or a top surface of the second dummy die.

### BACKGROUND

### Field

The field relates to integrated circuit packages and/or components having multiple dies.

### Description of the Related Art

Microelectronic assemblies generally include one or more integrated circuit (IC) dies (“chips”) which can be packaged for connection to an external device, such as a system board. One or more of such IC dies may be mounted on a circuit platform, such as a wafer for wafer-level-packaging (“WLP”), printed board (“PB”), a printed wiring board (“PWB”), a printed circuit board (“PCB”), a printed wiring assembly (“PWA”), a printed circuit assembly (“PCA”), a package substrate, an interposer, or a chip carrier. Additionally, one IC die may be mounted on another IC die. An interposer may be an IC die or other type of electronic component, and an interposer may be a passive or an active IC die, where the latter includes one or more active devices, such as transistors for example, and the former may or may not include any active or passive devices. Furthermore, an interposer may be formed like a PWB, and may include any circuit elements such as capacitors, resistors, or active devices. Additionally, an interposer can include at least one through-substrate-via.

The conventional method for fabricating some IC packages is expensive. For example, the conventional method includes multiple dielectric layer depositions and multiple chemical-mechanical polishing steps. The conventional method further includes long times for deep dielectric cavity etching and long times for deep cavity metal filling. All of these steps add cost to the process.

Accordingly, it would be desirable and useful to provide structures and methods for fabricating topographic packages, for example, topographic packages formed by direct hybrid bonding that addresses these problems.

### BRIEF DESCRIPTION OF THE DRAWINGS

Specific implementations will now be described with reference to the following drawings, which are provided by way of example, and not limitation.

FIGS. 1A-1D are cross-sectional diagrams illustrating a method of making hybrid bonded topographic packages according to some embodiments of the disclosed technology.

FIGS. 2A-2C are cross-sectional diagrams illustrating a method of making hybrid topographic packages according to other embodiments of the disclosed technology.

FIGS. 3A-3C are cross-sectional diagrams illustrating various embodiments of encapsulated hybrid topographic packages according to embodiments of the disclosed technology.

FIGS. 4A-4B schematically illustrate a process for forming a directly hybrid bonded structure without an intervening adhesive according to some embodiments.

FIG. 5 is a process flow diagram illustrating a method of making example integrated circuits according to some embodiments of the disclosed technology.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following description refers to integrated circuit packages. Specifically, the following description refers to integrated circuit packages having hybrid bonded integrated circuits.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 408a and/or 408b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. In some embodiments, the width of a conductive feature 406a of substrate 410a may be at least 5% larger than a width of the width of an opposite conductive feature 406b of substrate 410b. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen containing plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with nitogen bearing molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form a connection between elements. In such processes, the connections between the elements comprises an organic layer which is typically a poor thermal conductor, mechanically not as strong as bonded substrates. Further, the thermal expansion of the bonding polymeric adhesive layer is typically larger the thermal expansion of the bonded substrates.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the bonded elements at temperature higher than room temperature.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often-includes an intermetallic layer between the bonded elements and sharp interfaces with conductors from both elements. Additionally, the bonded metal can be subjected to reversal by reheating the bonded elements. Further, to strengthen the bonded element, an underfill layer is typically formed between the gap between bonded elements. By way of contrast, direct metal bonding as employed in hybrid bonding may not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding. Additionally, there is no gap for underfill between the bonded elements.

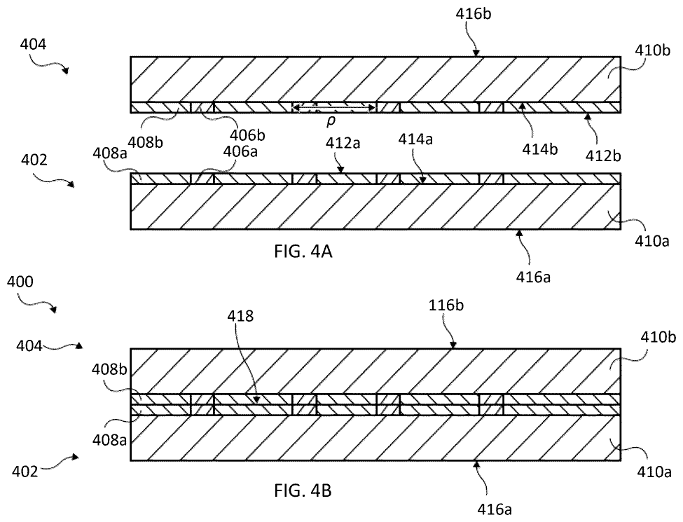

FIGS. 4A and 4B schematically illustrate cross-sectional side views of first and second elements 402, 404 prior to and after, respectively, a process for forming a directly bonded structure, and more particularly a hybrid bonded structure, according to some embodiments. In FIG. 4B, a bonded structure 400 comprises the first and second elements 402 and 404 that are directly bonded to one another at a bond interface 418 without an intervening adhesive or underfill. Conductive features 406a of a first element 402 may be electrically connected to corresponding conductive features 406b of a second element 404. In the illustrated hybrid bonded structure 400, the conductive features 406a are directly bonded to the corresponding conductive features 406b without intervening solder or conductive or non-conductive adhesive.

The conductive features 406a and 406b of the illustrated embodiment are embedded in, and can be considered part of, a first bonding layer 408a of the first element 402 and a second bonding layer 408b of the second element 404, respectively. Field regions of the bonding layers 408a, 408b extend between and partially or fully surround the conductive features 406a, 406b. The bonding layers 408a, 408b can comprise layers of non-conductive materials suitable for direct bonding, as described above, and the field regions are directly bonded to one another without an adhesive. The non-conductive bonding layers 408a, 408b can be disposed on respective front sides 414a, 414b of base substrate portions 410a, 410b.

The first and second elements 402, 404 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 402, 404, and back-end-of-line (BEOL) interconnect layers over such semiconductor portions. The bonding layers 408a, 408b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 410a, 410b, and can electrically communicate with at least some of the conductive features 406a, 406b. Active devices and/or circuitry can be disposed at or near the front sides 414a, 414b of the base substrate portions 410a, 410b, and/or at or near opposite backsides 416a, 416b of the base substrate portions 410a, 410b. In other embodiments, the base substrate portions 410a, 410b may not include active circuitry, but may instead comprise dummy substrates, passive interposers, passive optical elements (e.g., glass substrates, gratings, lenses), etc. The bonding layers 408a, 408b are shown as being provided on the front sides of the elements, but similar bonding layers can be additionally or alternatively provided on the back sides of the elements.

In some embodiments, the base substrate portions 410a, 410b can have significantly different coefficients of thermal expansion (CTEs), and bonding elements that include such different based substrate portions can form a heterogenous bonded structure. The CTE difference between the base substrate portions 410a and 410b, and particularly between bulk semiconductor (typically single crystal) portions of the base substrate portions 410a, 410b, can be greater than 5 ppm/° C. or greater than 10 ppm/° C. For example, the CTE difference between the base substrate portions 410a and 410b can be in a range of 5 ppm/° C. to 400 ppm/° C., 5 ppm/° C. to 40 ppm/° C., 10 ppm/° C. to 400 ppm/° C., or 10 ppm/° C. to 40 ppm/° C.

In some embodiments, one of the base substrate portions 410a, 410b can comprise optoelectronic single crystal materials, including perovskite materials, that are useful for optical piezoelectric or pyroelectric applications, and the other of the base substrate portions 410a, 410b comprises a more conventional substrate material. For example, one of the base substrate portions 410a, 410b comprises lithium tantalate (LiTaO3) or lithium niobate (LiNbO3), and the other one of the base substrate portions 410a, 410b comprises silicon (Si), quartz, fused silica glass, sapphire, or a glass. In other embodiments, one of the base substrate portions 410a, 410b comprises a III-V single semiconductor material, such as gallium arsenide (GaAs) or gallium nitride (GaN), and the other one of the base substrate portions 410a, 410b can comprise a non-III-V semiconductor material, such as silicon (Si), or can comprise other materials with similar CTE, such as quartz, fused silica glass, sapphire, or a glass. In still other embodiments, one of the base substrate portions 410a, 410b comprises a semiconductor material and the other of the base substrate portions 410a, 410b comprises a packaging material, such as a glass, organic or ceramic substrate.

In some arrangements, the first element 402 can comprise a singulated element, such as a singulated integrated device die. In other arrangements, the first element 402 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 404 can comprise a singulated element, such as a singulated integrated device die. In other arrangements, the second element 404 can comprise a carrier or substrate (e.g., a semiconductor wafer). The embodiments disclosed herein can accordingly apply to wafer-to-wafer (W2W), die-to-die (D2D), or die-to-wafer (D2W), or die-to-panel, or die-to-package, or die-to-substrate, or substrate-to-substrate, or substrate-to-package, or package-to-package bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 402, 404 are shown, any suitable number of elements can be stacked in the bonded structure 400. For example, a third element (not shown) can be stacked on the second element 404, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 402. In some embodiments, a laterally stacked additional element may be smaller than the second element. In some embodiments, the bonded structure can be encapsulated with an insulating material, such as an inorganic or organic dielectric material. The inorganic dielectric may comprise for example, silicon oxide, silicon nitride, silicon carbide, silicon oxynitrocarbide, etc. The organic encapsulate may include particulate reinforced organic material for example low CTE molding material having CTE between 5 and 25 ppm/° C. One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 408a, 408b, the bonding layers 408a, 408b can be prepared for direct bonding. Non-conductive bonding surfaces 412a, 412b at the upper or exterior surfaces of the bonding layers 408a, 408b can be prepared for direct bonding by polishing, for example, by chemical mechanical polishing (CMP). The roughness of the polished bonding surfaces 412a, 412b can be less than 30 Å rms. For example, the roughness of the bonding surfaces 412a and 412b can be in a range of about 0.1 Å rms to 15 Å rms, 0.5 Å rms to 10 Årms, or 1 Å rms to 5 Å rms. Polishing can also be tuned to leave the conductive features 406a, 406b recessed relative to the field regions of the bonding layers 408a, 408b.

Preparation for direct bonding can also include cleaning and exposing one or both of the bonding surfaces 412a, 412b to a plasma and/or etchants to activate at least one of the surfaces 412a, 412b. In some embodiments, one or both of the surfaces 412a, 412b can be terminated with a species after activation or during activation (e.g., during the plasma and/or etch processes). Without being limited by theory, in some embodiments, the activation process can be performed to break chemical bonds at the bonding surface(s) 412a, 412b, and the termination process can provide additional chemical species at the bonding surface(s) 412a, 412b that alters the chemical bond and/or improves the bonding energy during direct bonding. In some embodiments, the activation and termination are provided in the same step, e.g., a plasma to activate and terminate the surface(s) 412a, 412b. In other embodiments, one or both of the bonding surfaces 412a, 412b can be terminated in a separate treatment to provide the additional species for direct bonding. In various embodiments, the terminating species can comprise nitrogen. For example, in some embodiments, the bonding surface(s) 412a, 412b can be exposed to a nitrogen-containing plasma. Other terminating species can be suitable for improving bonding energy, depending upon the materials of the bonding surfaces 412a, 412b. Further, in some embodiments, the bonding surface(s) 412a, 412b can be exposed to fluorine. For example, there may be one or multiple fluorine concentration peaks at or near a bond interface 418 between the first and second elements 402, 404. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 400, the bond interface 418 between two non-conductive materials (e.g., the bonding layers 408a, 408b) can comprise a very smooth interface with higher nitrogen (or other terminating species) content and/or fluorine concentration peaks at the bond interface 418. In some embodiments, the nitrogen and/or fluorine concentration peaks may be detected using various types of inspection techniques, such as SIMS techniques. The polished bonding surfaces 412a and 412b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 408a and 408b can be directly bonded to one another without an adhesive. In some embodiments, the elements 402, 404 are brought together at room temperature, without the need for application of a voltage, and without the need for application of external pressure or force beyond that used to initiate contact between the two elements 402, 404. Contact alone can cause direct bonding between the non-conductive surfaces of the bonding layers 408a, 408b (e.g., covalent dielectric bonding). Subsequent annealing of the bonded structure 400 can cause the conductive features 406a, 406b to directly bond.

In some embodiments, prior to direct bonding, the conductive features 406a, 406b are recessed relative to the surrounding field regions, such that a total gap between opposing contacts after dielectric bonding and prior to anneal is less than 15 nm, or less than 10 nm. Because the recess depths for the conductive features 406a and 406b can vary across each element, due to process variation, the noted gap can represent a maximum or an average gap between corresponding conductive features 406a, 406b of two joined elements (prior to anneal). Upon annealing, the conductive features 406a and 406b can expand and contact one another to form a metal-to-metal direct bond.

During annealing, the conductive features 406a, 406b (e.g., metallic material) can expand while the direct bonds between surrounding non-conductive materials of the bonding layers 408a, 408b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding. For example, the annealing temperature may range between 100 to 400° C. and between 150 to 350° C., and the annealing time may range between 2 minutes to 4 hours or longer. In practice, the higher the annealing temperature the shorter the annealing time. In one example, the bonded element 400 may be annealed at 250° C. for less than 2 hours, for example 90 minutes.

In various embodiments, the conductive features 406a, 406b can comprise discrete pads, contacts, electrodes, or traces at least partially embedded in the non-conductive field regions of the bonding layers 408a, 408b. In some embodiments, the conductive features 406a, 406b can comprise exposed contact surfaces of TSVs (e.g., through silicon vias).

As noted above, in some embodiments, in the elements 402, 404 of FIG. 4A prior to direct bonding, portions of the respective conductive features 406a and 406b can be recessed below the non-conductive bonding surfaces 412a and 412b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 406a, 406b or to average depths of the recesses relative to local non-conductive field regions. Even for an individual conductive feature 406a, 406b, the vertical recess can vary across the bond surfaces 412a or 412b or both bonding surfaces. The recess can be measured on conductive features 406a, 406b located across the bonding surface, for example at or near the edge, the middle and center of the bonding surface 412a and 412b.

Beneficially, the use of hybrid bonding techniques (such as Direct Bond Interconnect, or DBI®, techniques commercially available from Adeia of San Jose, CA) can enable high density of connections between conductive features 406a, 406b across the direct bond interface 418 (e.g., small or fine pitches for regular arrays).

In some embodiments, a pitch p of the conductive features 406a, 406b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 406a and 406b to one of the lateral dimensions (e.g., a diameter) of the bonding pad is less than is less than 20, or less than 10, or less than 5, or less than 3 and sometimes desirably less than 2. In various embodiments, the conductive features 406a and 406b and/or traces can comprise copper or copper alloys, although other metals may be suitable, and may comprise nickel, aluminum, cobalt, gold, silver, tin, molybdenum, indium, manganese or alloys thereof. The conductive features disclosed herein, such as the conductive features 406a and 406b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 402, 404, as shown, the orientations of one or more conductive features 406a, 406b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 406b in the bonding layer 408b (and/or at least one internal conductive feature, such as a BEOL feature) of the upper element 404 may be tapered or narrowed upwardly, away from the bonding surface 412b. By way of contrast, at least one conductive feature 406a in the bonding layer 408a (and/or at least one internal conductive feature, such as a BEOL feature) of the lower element 402 may be tapered or narrowed downwardly, away from the bonding surface 412a. Similarly, any bonding layers (not shown) on the backsides 416a, 116b of the elements 402, 404 may taper or narrow away from the backsides, with an opposite taper orientation relative to front side conductive features 406a, 406b of the same element.

As described above, in an anneal phase of hybrid bonding, the conductive features 406a, 406b can expand and contact one another to form a metal-to-metal direct bond. In some embodiments, the materials of the conductive features 406a, 406b of opposite elements 402, 404 can interdiffuse during the annealing process. In some embodiments, metal grains grow into each other across the bond interface 418. In some embodiments, the metal is or includes copper, which can have grains oriented along the 111 crystal plane for improved copper diffusion across the bond interface 418. In some embodiments, the conductive features 406a and 406b may include nanotwinned copper grain structure, which can aid in merging the conductive features during anneal. There is substantially no gap between the non-conductive bonding layers 408a and 408b at or near the bonded conductive features 406a and 406b. In some embodiments, a barrier layer may be provided under and/or laterally surrounding the conductive features 406a and 406b (e.g., which may include copper). In other embodiments, however, there may be no barrier layer under the conductive features 406a and 406b.

As discussed above, conventional methods for fabricating IC packages includes multiple dielectric layer depositions and multiple chemical-mechanical polishing steps, which add time and cost to the fabrication of the IC packages. Additional discussions of methods for fabricating IC packages can be found in co-pending applications U.S. application Ser. No. 18/194,591, filed Mar. 31, 2023, and U.S. application Ser. No. 18/194,571, filed Mar. 31, 2023, hereby incorporated by reference in their entirety. Embodiments of methods disclosed herein apply vertically stacked dummy dies within the topography to reduce coating and polishing of multiple dielectric layers. That is, embodiment methods disclosed herein reduce the number of coating and polishing steps. In embodiments, the dummy dies include through substrate vias (TSV) (e.g., through silicon vias) and may include passive electronic elements, such as resistors, capacitors and the like. The embodiments described herein include one or more of the following advantages: elimination of the deposition of multiple coatings of thick dielectric layers; elimination of the multiple polishing of the thick dielectric layers; elimination of long times for etching deep dielectric cavities; elimination of long metal coating times required to fill the etched deep dielectric cavities; and elimination of the long CMP times needed to remove the unwanted coated metal from prior coating processes.

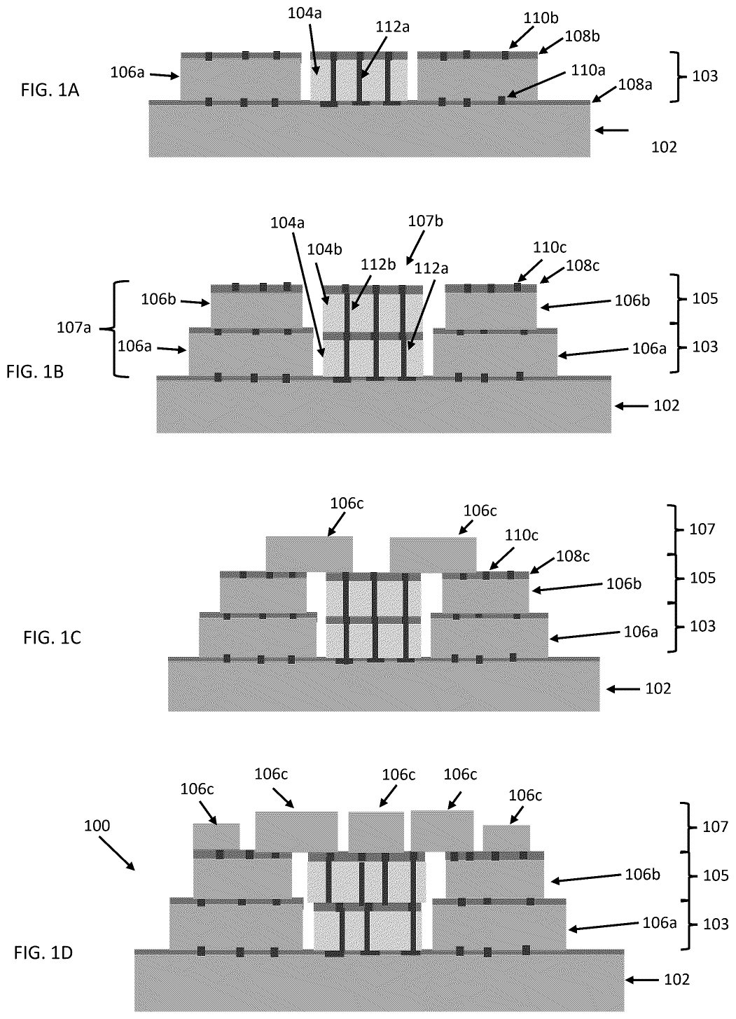

FIGS. 1A-1D are cross-sectional diagrams illustrating a method of making hybrid bonded topographic packages according to some embodiments of the disclosed technology. As illustrated in FIG. 1A, a substrate 102 is provided. The substrate may be made of any suitable material, such as a semiconductor material including silicon, III-V compound semiconductors, for example but not limited to, GaAs, InP, InGaP, InGaAs, InGaAsP, and II-VI semiconductors, for example but not limited to, CdSe, ZnSe, CdTe, ZnTe. In other embodiments, the substrate 102 can comprise an insulating material, such as a dielectric substrate (e.g., a glass substrate), a ceramic substrate, an organic substrate (e.g., with an inorganic bonding layer thereon), a package etc. A first insulating layer 108a (e.g., an inorganic dielectric) may be formed (e.g., deposited) on the substrate 102. First conductive features 110a may be formed in the first insulating layer 108a to provide current from the substrate. The first insulating layer may be made of any suitable dielectric material, for example but not limited to, an inorganic dielectric such as silicon oxide (SiO₂). One or more first device dies 106a may be attached to the substrate 102 in a first device level 103. Further, one or more first dummy dies 104a may be attached to the substrate 102 in the first device level 103.

In embodiments, the one or more first device dies 106a can comprise active circuitry at top or bottom sides of the one or more first device dies 106a. That is, the one or more of the device dies 106a may include one or multiple transistors. In some embodiments, the first device dies 106a may comprise stacked dies. In some embodiments, the one or more dummy dies 104a may comprise a semiconductor material (e.g., a block or die of silicon) without any active circuitry. For example, the one or more dummy dies 104a can be devoid of transistors. Alternatively, at least 50%, such as at least 65% (for example, at least 90% or at least 95%), of each of the top and bottom surfaces of the one or more dummy dies 104a may not include patterned transistors. Alternatively, the number of transistors in the one or more dummy dies 104a comprise less than 45%, such as less than 35%, of the number of transistors in the first device dies 106a. In some embodiments, the number of transistors in the one or more dummy dies 104a comprise less than 5%, such as less than 1%, of the number of transistors in the first device dies 106a. In addition, the one or more dummy dies 104a may include passive devices such as resistors, capacitors, transformers, inductors, heat transfer materials, etc. or just through substrate vias 112a, e.g. copper vias. In embodiments, the first dummy dies 104a may have first pass through conductive layers 112a. In the illustrated embodiment, the first pass through conductive layers 112a comprise through substrate vias (TSVs) that extend through the dummy die 104a. The first pass through conductive layers 112a allow current to flow from the substrate 102 to the second device level 105 (see FIG. 1B) and to power any passive components (not shown) in the first dummy device 104a. In embodiments, the one or more first device dies 106a and the one or more dummy dies 104a may be attached to the substrate 102 by hybrid bonding. Alternatively, the one or more first device dies 106a and the one or more dummy dies 104a (or any of the device dies or dummy dies described below) may be attached by soldering or using other types of adhesives. In some embodiments, the dummy dies 104a and the device dies 106a may have approximately the same thickness. Alternatively, the dummy dies 104a and the device dies 106a may have different thicknesses. In an embodiment, the first insulating layer may be a redistribution layer (RDL) or a wiring layer formed in the die's back-end-of-line (BEOL) layers, and can serve as a direct bonding (e.g., hybrid bonding) layer. As further illustrated in FIG. 1A, a second insulating layer 108b may be formed on top of the first device dies 106a and the first dummy dies 104a. In embodiments, the second insulating layer 108b may be a redistribution layer (RDL) or a wiring layer formed in the die's BEOL layers, and can serve as a direct bonding (e.g., hybrid bonding) layer. In some embodiments, one or more bonding layers (not shown) may be deposited on the bottom surfaces of the first dummy dies 104a and the first device dies 106a.

As illustrated in FIG. 1B, second device dies 106b and second dummy dies 104b may be attached to the first device dies 106a and first dummy dies 104a, respectively. In this manner, a device die 107a stack and a dummy die stack 107b may be formed. In an embodiment, the one or more second device dies 106b and the one or more second dummy dies 104b may be attached to the first device dies 106a and first dummy dies 104a by hybrid bonding. In some embodiments, the second device dies 106b may comprise stacked dies. Similar to the first dummy dies 104a, the second dummy dies 104b may comprise stacked dummy dies having second pass through conductive layers 112b (e.g., TSVs). The second pass through conductive layers 112b allow current to flow from the first dummy dies 104a to the third device level 107 and to power any passive components (not shown) in the second dummy device 104b. As further illustrated in FIG. 1B, third insulating layer 108c may be formed on top of the second device dies 106b and the second dummy dies 104b. In embodiments, the third insulating layer 108c may be a redistribution layer (RDL) or a wiring layer formed in the die's BEOL layers, and can serve as a direct bonding (e.g., hybrid bonding) layer.

As illustrated in FIG. 1C, third device dies 106c may be attached to the second device dies 106b and the second dummy dies 104a. Alternative configurations of the third dies 106c are illustrated in FIG. 1D. As illustrated in FIG. 1D, the one or more third device dies 106c may be attached to the second device dies 106a and/or second dummy dies 104b. For example, additional third device dies 106c may be provided such that some of the second device dies 106b are only electrically connected to the third device dies 106c, some third device dies 106c are electrically connected to the second device dies 106b and the second dummy dies 104b and some dies are electrically connected only to the second dummy dies 104b. The third device dies 106c that span a gap between a second dummy die 104b and a second active die 106a may be referred to as a bridge die. Because the first and second through substrate vias 112a, 112b are electrically conductive, signals or power may be transferred through the first and second through substrate vias 112a, 112b to the third device dies 106c. In some embodiments, the third device dies 106c may communicate with both the dummy dies 104a, 104b and the second active dies 106b. The final hybrid topographic package 100 may have multiple third device dies 106c in attached in various configurations. Further, any of the third device dies 106c may be attached by hybrid bonding. In some embodiments, the third dies 106c may comprise pass through electrodes such as for example TSVs. In addition, as discussed in more detail below, the finished hybrid topographic package 100 may be coated with an encapsulant to protect the active dies, 106a, 106b, 106c. Further, as discussed above, the use of dummy dies 104a, 104b allows for the elimination of multiple deposition and CMP steps of dielectric layers used in the conventional fabrication process. In some embodiments, the substrate 102 remains in the finished hybrid topographic package 100. However, in other embodiments, the substrate 102 may be removed and the resulting reconstituted structure (without the substrate 102) may be bonded or attached to another one or more carriers.

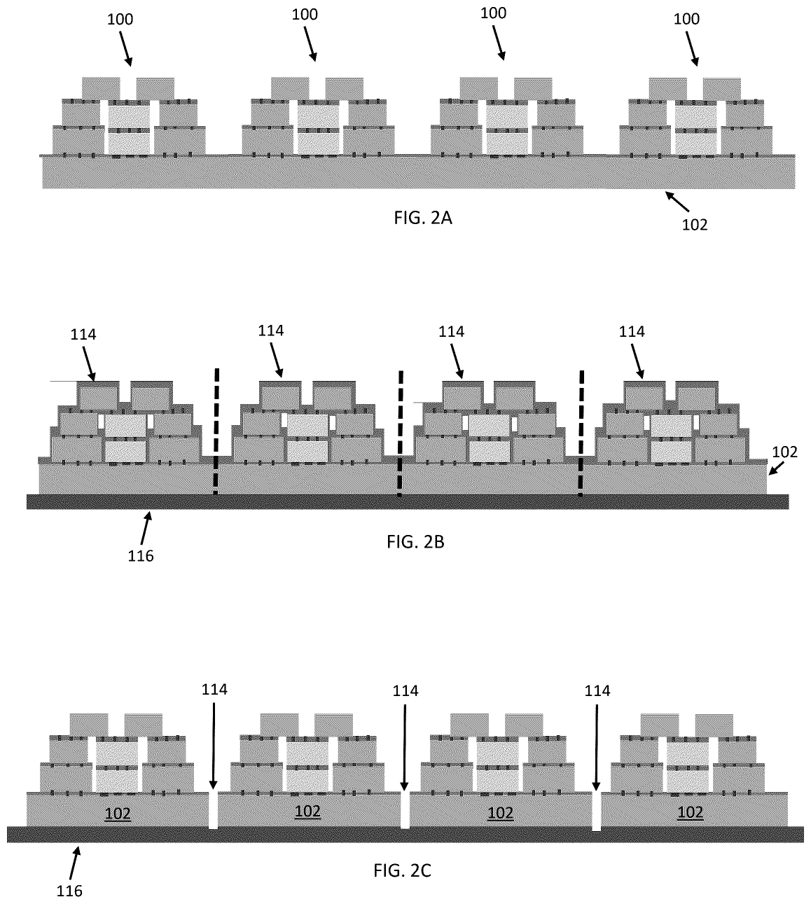

FIGS. 2A-2C are cross-sectional diagrams illustrating a method of making hybrid topographic packages 100 according to other embodiments of the disclosed technology. As illustrated in FIG. 2A, multiple hybrid topographic packages 100 may be formed on the substrate 102 simultaneously in a manner similar to the processes illustrated in FIGS. 1A-1C above. Next, as illustrated in FIG. 2B, the substrate 102 is attached to a carrier wafer 116, e.g., by way of an adhesive or tape. Then a protective coating 114 is deposited over the substrate 102 and the multiple hybrid topographic packages 100. Alternatively, the protective coating 114 may be deposited first and then the coated substate 102 and coated hybrid topographic packages 100 attached to the carrier wafer 116. In an embodiment, the protective coating comprises an organic material, such as a photoresist, which can protect the substrate 102 during singulation.

Next, as illustrated in FIG. 2C, the substrate 102 may be diced by any suitable method to singulate the multiple hybrid topographic packages 100. Suitable dicing methods include, for example, sawing, laser ablation, and plasma cutting. After singulating the substrate 102 into multiple hybrid topographic packages 100, the protective layer 114 may be removed, for example, using a suitable developing solution.

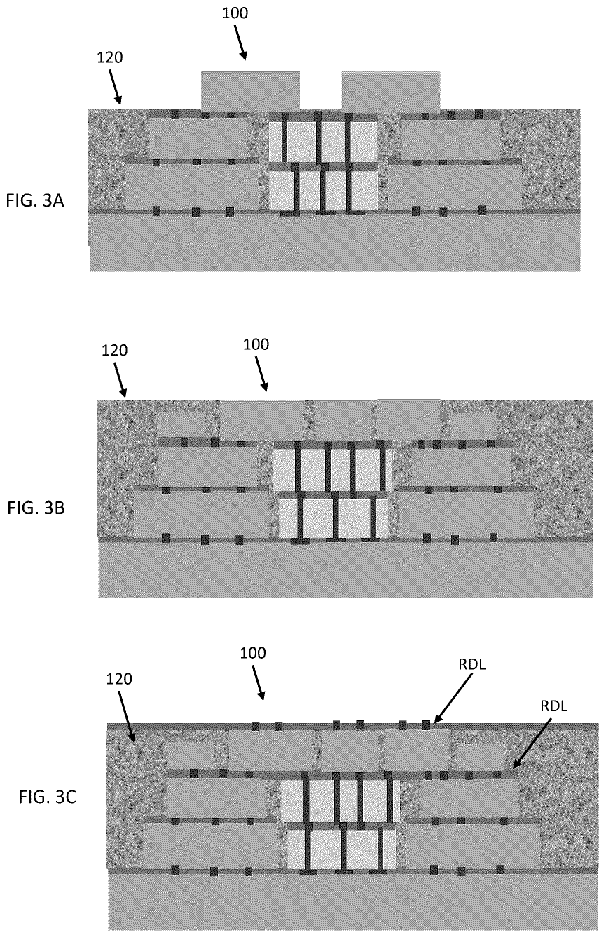

FIGS. 3A-3C illustrate an embodiment in which the electronic hybrid topographic packages 100 may be encapsulated with an encapsulant 120. Encapsulation protects the electrical components, e.g. dies from chemical (e.g. moisture), mechanical, electrical, and thermal environments. Encapsulation may be performed, for example, with an organic (e.g., polymer) encapsulation process in which the hybrid topographic package 100 is coated with a polymer which is then polymerized. The encapsulant 120 may be made of any suitable material including, but are not limited to, epoxy resins and silicones. Further, one or more additives may added to the polymer such as, but not limited to, hardeners, flame retardants and fillers. For example, silica particles may be added to the encapsulant to lower the coefficient of thermal expansion (CTE) of the encapsulant. Encapsulation may be performed with either solid or liquid starting materials. When a solid encapsulant is used, the solid encapsulant is typically provided as a powder but may be provided as pellets or any other suitable form. The solid encapsulant may be provided to a mold and heated until it is a liquid. The hybrid topographic package 100 is then pressed into the mold, resulting in the hybrid topographic package 100 being coated. When using an epoxy resin, the resin may be exposed to ultraviolet light to cure (harden) the epoxy. When using a liquid polymer as a starting material, the liquid polymer may be poured in a mold and the topographic package 100 pressed into the mold as when using a solid starting material. Alternatively, the liquid polymer may be poured or sprayed over the hybrid topographic package 100.

FIG. 3A illustrates an embodiment in which the hybrid topographic package 100 is partially encapsulated. As illustrated in FIG. 3A, the encapsulant 120 covers the substrate 120, the first and second dummy dies 104a, 104b and the first and second device dies 106a, 106b. As further illustrated, the first and second dummy dies 104a, 104b and the first and second device dies 106a, 106b are completely surrounded by the encapsulant 120. FIG. 3B illustrates an embodiment in which the hybrid topographic package 100 is fully encapsulated. As illustrated in FIG. 3B, the first and second dummy dies 104a, 104b, the first and second device dies 106a, 106b and the third device dies 106c are surrounded by the encapsulant 120 with the exception of the top sides of the third device dies 106c. In some embodiments (not shown) a cooling layer may be disposed over the top surface of the package 100. The incorporation of the dummy dies 104a and 104b assist in the more effective heat transfer from the substrate to the cooling layer above. FIG. 3C illustrates an embodiment in which the hybrid topographic package 100 in which the third insulting layer 108c includes a redistribution layer RDL. Alternatively as illustrated in FIG. 3C, the hybrid topographic package 100 may include a redistribution layer RDL on the top of the hybrid topographic package 100 in addition to or instead of the redistribution layer RDL in the third insulating layer 108c. In some embodiments, for example, after the molding step, the backside of the third dies 106c with or without TSVs may be thinned and planarized. The TSVs may be exposed on the thinned back side. In embodiments, the second insulating layer 108b may be a redistribution layer (RDL) or a wiring layer formed over the back side of thinned dies 106. In some embodiments, a contact pad may be formed on the exposed TSVs on the backside of dies 106c. In some embodiments, the backside of the substrate 102 may be thinned and polished if needed, and the cooling layer may be disposed over the top surface of the package 100 (not shown).

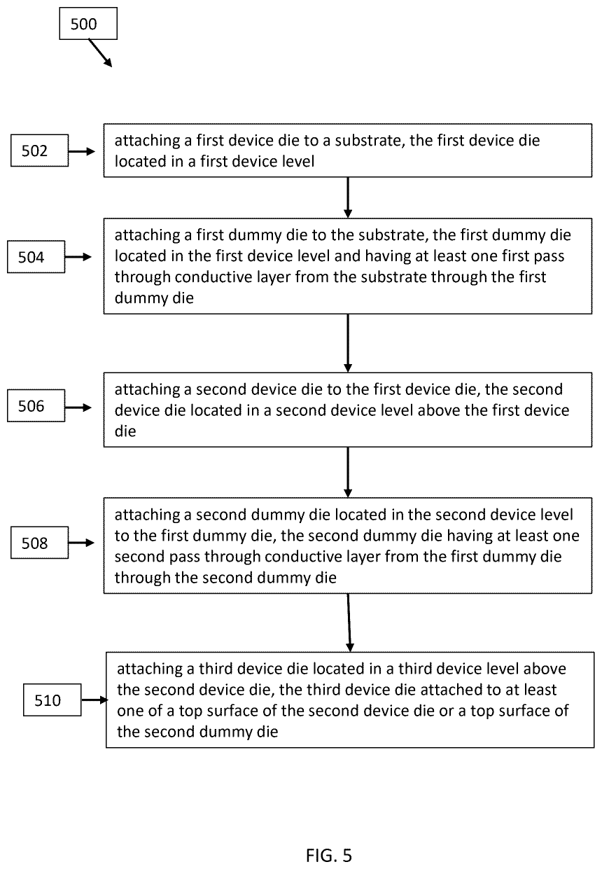

FIG. 5 is a process flow diagram illustrating a method 500 of making example integrated circuits according to some embodiments of the disclosed technology. In a first step, 502, the method includes attaching a first device die 106a to a substrate 102, the first device die 106a located in a first device level 103. The next step 504 includes attaching a first dummy die 104a to the substrate 102, the first dummy die 104a located in the first device level 103 and having at least one first pass through conductive layer 112 from the substrate 102 through the first dummy die 104a. The next step 506 includes attaching a second device die 106b to the first device die 106a, the second device die 106b located in a second device level 105 above the first device die 106a. The next step 508 includes attaching a second dummy die 104b located in the second device level 105 to the first dummy die 104a, the second dummy die 104a having at least one second pass through conductive layer 112b from the first dummy die 104a through the second dummy die 104b. The next step includes attaching a third device die 106c located in a third device level 107 above the second device die 106b, the third device die 106c attached to at least one of a top surface of the second device die 106b or a top surface of the second dummy die 104b.

### EXAMPLES

Example 1. An electronic component comprising: a first device die, the first device die located in a first device level; a first dummy die, the first dummy die located in the first device level and having at least one first pass through conductive layer through the first dummy die; a second device die disposed in a second device level above the first device die, the second device die attached to the first device die; a second dummy die disposed in the second device level, the second dummy die attached to the first dummy die and having at least one second pass through conductive layer electrically connected to the at least one first pass through conductive layer; and a third device die located in a third device level above the second device die, the third device die attached to at least one of a top surface of the second device die or a top surface of the second dummy die.

Example 2. The electronic component of Example 1, wherein the first device die is attached to a substrate.

Example 3. The electronic component of Example 1, wherein at least one of the first device die and the first dummy die are attached to the substrate by direct hybrid bonding.

Example 4. The electronic component of Example 1, wherein at least one of the second device die and the second dummy die are attached to the first device die and the first dummy die, respectively.

Example 5. The electronic component of Example 1, wherein third device die is attached to the second device die, the second dummy die or both the second device die and the second dummy die.

Example 6. The electronic component of Example 1, wherein the third device die is electrically connected to the second device die with a bonding layer comprising conductive features.

Example 7. The electronic component of Example 1, wherein the third device die is electrically connected to the second device die and to the substrate.

Example 8. The electronic component of Example 1, wherein the third device die is electrically connected to the second dummy die.

Example 9. The electronic component of Example 1, wherein the third device die is electrically connected to the second dummy die.

Example 10. The electronic component of Example 1, further comprising a first bonding layer located between the substrate and at least one of the first device die or first dummy die.

Example 11. The electronic component of Example 1, further comprising at least one second bonding layer located between the first device die and the second device die or between the first dummy die and the second dummy die.

Example 12. The electronic component of Example 1, further comprising at least one second bonding layer located between the second device die and the third device die or between the second dummy die and the third device die.

Example 13. The electronic component of Example 1, further comprising at least one passive electronic element in at least one of the first dummy die and second dummy die.

Example 14. The electronic component of Example 1, further comprising an encapsulant encapsulating the at least the first device die, the first dummy die, the second device die and the second dummy die.

Example 15. The electronic component of Example 1, wherein the electronic component is configured to receive power through the substrate.

Example 16. A method of making an electronic component comprising: attaching a first device die to a substrate, the first device die located in a first device level; attaching a first dummy die to the substrate, the first dummy die located in the first device level and having at least one first pass through conductive layer through the first dummy die; attaching a second device die to the first device die, the second device die located in a second device level above the first device die; attaching a second dummy die located in the second device level to the first dummy die, the second dummy die having at least one second pass through conductive layer from the first dummy die through the second dummy die; and attaching a third device die located in a third device level above the second device die, the third device die attached to at least one of a top surface of the second device die or a top surface of the second dummy die.

Example 17. The method of Example 16, wherein any of the steps of attaching comprises hybrid bonding.

Example 18. The method of Example 16, wherein the third device die is electrically connected to the second device die and to the substrate via the first pass through conductive layer and second pass through conductive layer.

Example 19. The method of Example 16, further comprising forming a first bonding layer located between the substrate and at least one of the first device die or first dummy die.

Example 20. The method of Example 16, further comprising forming at least one second bonding layer located between the first device die and the second device die or between the first dummy die and the second dummy die.

Example 21. The method of Example 16, further comprising forming at least one third bonding layer located between the second device die and the third device die or between the second dummy die and the third device die.

Example 22. The method of Example 16, further comprising at least one passive electronic element in at least one of the first dummy die or the second dummy die.

Example 23. The method of Example 16, further comprising, after attaching the third device die, encapsulating thefirst device die, the first dummy die, the second device die, and the second dummy die.

Example 24. The method of Example 16, wherein a plurality of electronic components are formed on a wafer.

Example 25. The method of Example 24, wherein the plurality of electronic components are singulated by dicing the wafer.

Example 26. The method of Example 25, further comprising forming a protective layer over the plurality of electronic components and the wafer prior to singulating.

Example 27. The method of Example 26, further comprising removing the protective layer after singulating.

Example 28. An electronic component comprising: a first die stack comprising: a first device die; and a second device die hybrid bonded to the first device die; a second die stack disposed adjacent the first die stack, the second die stack comprising: a first dummy die having a first through substrate via (TSV); and a second dummy die attached to the first dummy die, the second dummy die having a second TSV electrically connected to the first TSV; and an encapsulant at least partially encapsulating the first and second die stacks, the encapsulant disposed at least between the first and second die stacks.

Example 29. The electronic component of Example 28, further comprising:
a third die stack adjacent the second die stack such that the second die stack is located between the first die stack and the third die stack, the third die stack comprising: a first device die; and a second device die hybrid bonded to the first device die.

Example 30. The electronic component of Example 28, wherein the encapsulant is located on an outer side of first stack between an outer edge of the component and the first stack.

Example 31. The electronic component of Example 28, further comprising at least one bridging device die hybrid bonded to the second device die and the second dummy die.

Example 32. The electronic component of Example 31, wherein the encapsulant at least partially encapsulates the at least one bridging die.

Example 33. The electronic component of Example 31, further comprising a redistribution layer on top of the encapsulant.

Example 34. The electronic component of Example 28, further comprising passive devices located in the at least one of the first or second dummy dies.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An electronic component comprising:
a first device die, the first device die located in a first device level;
a first dummy die, the first dummy die located in the first device level and having at least one first pass through conductive layer through the first dummy die;
a second device die disposed in a second device level above the first device die, the second device die attached to the first device die;
a second dummy die disposed in the second device level, the second dummy die attached to the first dummy die and having at least one second pass through conductive layer electrically connected to the at least one first pass through conductive layer; and
a third device die located in a third device level above the second device die, the third device die attached to at least one of a top surface of the second device die or a top surface of the second dummy die.

2. The electronic component of claim 1, wherein the first device die is attached to a substrate.

3. The electronic component of claim 1, wherein at least one of the first device die and the first dummy die are attached to the substrate by direct hybrid bonding.

4. The electronic component of claim 1, wherein at least one of the second device die and the second dummy die are attached to the first device die and the first dummy die, respectively.

5. The electronic component of claim 1, wherein third device die is attached to the second device die, the second dummy die or both the second device die and the second dummy die.

6. The electronic component of claim 1, wherein the third device die is electrically connected to the second device die with a bonding layer comprising conductive features.

7. The electronic component of claim 1, wherein the third device die is electrically connected to the second device die and to the substrate.

8. The electronic component of claim 1, wherein the third device die is electrically connected to the second dummy die.

9. The electronic component of claim 1, wherein the third device die is electrically connected to the second dummy die.

10. The electronic component of claim 1, further comprising a first bonding layer located between the substrate and at least one of the first device die or first dummy die.

11. The electronic component of claim 1, further comprising at least one second bonding layer located between the first device die and the second device die or between the first dummy die and the second dummy die.

12. The electronic component of claim 1, further comprising at least one second bonding layer located between the second device die and the third device die or between the second dummy die and the third device die.

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. An electronic component comprising:
a first die stack comprising:
a first device die; and
a second device die hybrid bonded to the first device die;
a second die stack disposed adjacent the first die stack, the second die stack comprising:
a first dummy die having a first through substrate via (TSV); and
a second dummy die attached to the first dummy die, the second dummy die having a second TSV electrically connected to the first TSV; and
an encapsulant at least partially encapsulating the first and second die stacks, the encapsulant disposed at least between the first and second die stacks.

29. The electronic component of claim 28, further comprising:
a third die stack adjacent the second die stack such that the second die stack is located between the first die stack and the third die stack, the third die stack comprising:
a first device die; and
a second device die hybrid bonded to the first device die.

30. The electronic component of claim 28, wherein the encapsulant is located on an outer side of first stack between an outer edge of the component and the first stack.

31. The electronic component of claim 28, further comprising at least one bridging device die hybrid bonded to the second device die and the second dummy die.

32. The electronic component of claim 31, wherein the encapsulant at least partially encapsulates the at least one bridging die.

33. The electronic component of claim 31, further comprising a redistribution layer on top of the encapsulant.

34. (canceled)

35. An electronic component comprising:
a first die stack comprising:
a first device die; and
a second device die hybrid bonded to the first device die;
a second die stack disposed adjacent the first die stack, the second die stack comprising:
a first dummy die and
a second dummy die attached to the first dummy die.

36. The electronic component of claim 35, further comprising an encapsulant disposed at least between the first and second die stacks.
